(19) United States
(12) Patent Application Publication
(10) Pub. No.: US 2009/0168513 A1
(43) Pub. Date: Jul. 2, 2009

(54) MULTIPLE LEVEL CELL MEMORY DEVICE WITH IMPROVED RELIABILITY

(76) Inventor: Tomoharu Tanaka, Yokohama (JP)

Correspondence Address: LEFFERT JAY & POLGLAZE, P.A., P.O. BOX 581009, MINNEAPOLIS, MN, 55458-1009, US

(21) Appl. No.: 12/059,572

(22) Filed: Mar. 31, 2008

(30) Foreign Application Priority Data
Dec. 26, 2007 (JP) 2007-335262

(51) Int. Cl. G11C 16/04; G11C 16/06

(52) U.S. Cl. 365/185.03; 365/185.17; 365/185.18

(57) ABSTRACT

The reliability of multiple level cells in a memory device should be increased by programming the ends of the series strings of memory cells differently than the remaining quantity of memory cells of the series string. The end cells closest to select gate source and select gate drain transistors can be programmed as single level cells while the remaining cells of the string are programmed as multiple level cells. Another embodiment can program only one or more cells at the source end of the series string as single level cells. Still another embodiment can skip programming of the cells at either only the source end or both the source end and the drain end of the series string.

### TECHNICAL FIELD OF THE INVENTION

The present invention relates generally to memory devices and, in a particular embodiment, the present invention relates to non-volatile memory devices.

### BACKGROUND OF THE INVENTION

Memory devices are typically provided as internal, semiconductor, integrated circuits in computers or other electronic devices. There are many different types of memory including random-access memory (RAM), read only memory (ROM), dynamic random access memory (DRAM), synchronous dynamic random access memory (SDRAM), and flash memory.

Flash memory devices have developed into a popular source of non-volatile memory for a wide range of electronic applications. Flash memory devices typically use a one-transistor memory cell that allows for high memory densities, high reliability, and low power consumption. Common uses for flash memory include personal computers, personal digital assistants (PDAs), digital cameras, and cellular telephones. Program code and system data such as a basic input/output system (BIOS) are typically stored in flash memory devices for use in personal computer systems.

As the performance and complexity of electronic systems increase, the requirement for additional memory in a system also increases. However, in order to continue to reduce the costs of the system, the parts count must be kept to a minimum. This can be accomplished by increasing the memory density of an integrated circuit.

FIG. 1 illustrates a portion of a typical prior art memory array. For purposes of clarity, this figure does not show all of the elements typically required in a memory array. For example, only three bit lines are shown (BL1, BL2, BLN) when the number of bit lines required actually depends upon the memory density and chip architecture. The bit lines are subsequently referred to as (BL1-BLN). The bit lines (BL1-BLN) are eventually coupled to sense amplifiers (not shown) that detect the state of each cell.

The array is comprised of an array of floating gate cells 101 arranged in NAND series memory strings 104, 105. Each of the floating gate cells 101 are coupled drain to source in each series chain 104, 105. A word line (WL0-WL31) that spans across multiple series strings 104, 105 is coupled to the control gates of every floating gate cell in a row in order to control their operation.

In operation, the word lines (WL0-WL31) bias the individual floating gate memory cells in the selected NAND series strings 104, 105 to be erased, written to, or read from and operate the remaining floating gate memory cells in each series string 104, 105 in a pass through mode. Each series string 104, 105 of floating gate memory cells is coupled to a source line 106 by a source select gate 116, 117 and to an individual bit line (BL1-BLN) by a drain select gate 112, 113. The source select gates 116, 117 are controlled by a source select gate control line SG(S) 118 coupled to their control gates. The drain select gates 112, 113 are controlled by a drain select gate control line SG(D) 114.

Memory density can be increased by using multiple level cells (MLC). MLC memory can increase the amount of data stored in an integrated circuit without adding additional cells and/or increasing the size of the die. The MLC method stores two or more data bits in each memory cell.

MLC requires tight control of the threshold voltages in order to use multiple threshold levels per cell. One problem with non-volatile memory cells that are closely spaced, and MLC in particular, is the floating gate-to-floating gate capacitive coupling that causes interference between cells. The interference can shift the threshold voltage of neighboring cells as one cell is programmed. This is referred to as a program disturb condition that affects cells that are not desired to be programmed.

An MLC memory device also has a lower reliability than a single level cell (SLC) memory device due, in part, to the increased quantity of states requiring more closely spaced threshold voltages. Also, gate induced drain leakage (GIDL) can also cause a problem in the series strings of the MLC memory device.

The higher voltages required for programming MLC can cause a breakdown phenomenon in the select gates of the series string. A potential level of a diffusion layer is pulled up by the program voltage via capacitive coupling. This adverse effect is transported through electrons in the diffusion layer that is shared by the series string end cells and the select gates. The GIDL makes the programming of the end cells of the series strings less reliable.

For the reasons stated above, and for other reasons stated below that will become apparent to those skilled in the art upon reading and understanding the present specification, there is a need in the art to increase the reliability of multiple level cell memory devices.

### BRIEF DESCRIPTION OF THE DRAWINGS

FIG. 1 shows a simplified diagram of a portion of a prior art NAND flash memory array.

FIG. 2 shows one embodiment of a NAND series memory string incorporating two extra memory cells.

FIG. 3 shows an alternate embodiment of a NAND series memory string incorporating two extra memory cells.

FIG. 4 shows another alternate embodiment of a NAND series memory string incorporating two extra memory cells.

FIG. 5 shows another alternate embodiment of a NAND series memory string incorporating two extra memory cells.

FIG. 6 shows another alternate embodiment of a NAND series memory string incorporating one extra memory cell.

FIG. 7 shows another alternate embodiment of a NAND series memory string incorporating one extra memory cell.

FIG. 8 shows another alternate embodiment of a NAND series memory string incorporating one extra memory cell.

FIG. 9 shows a block diagram of one embodiment of a memory system that can incorporate the disclosed NAND series memory strings.

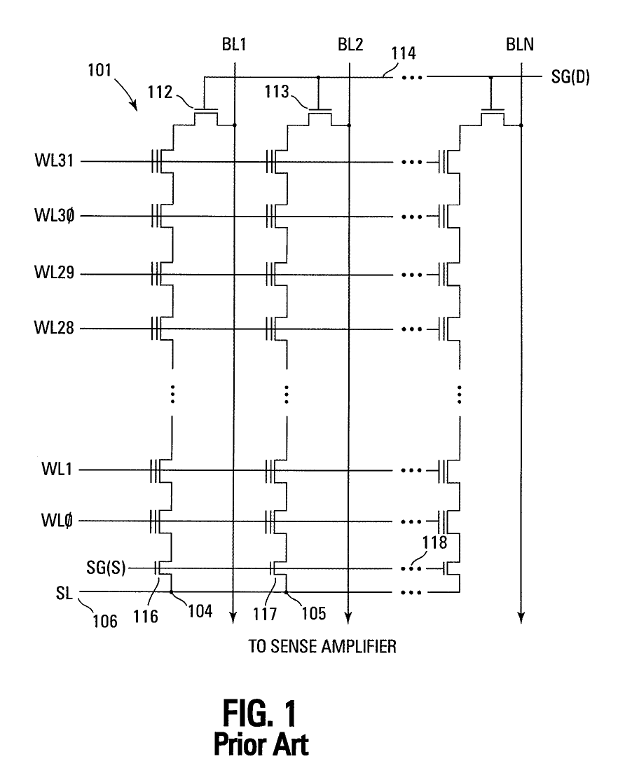

### DETAILED DESCRIPTION

In the following detailed description of the invention, reference is made to the accompanying drawings that form a part hereof and in which is shown, by way of illustration, specific embodiments in which the invention may be practiced. In the drawings, like numerals describe substantially similar components throughout the several views. These embodiments are described in sufficient detail to enable those skilled in the art to practice the invention. Other embodiments may be utilized and structural, logical, and electrical changes may be made without departing from the scope of the present invention. The following detailed description is, therefore, not to be taken in a limiting sense, and the scope of the present invention is defined only by the appended claims and equivalents thereof.

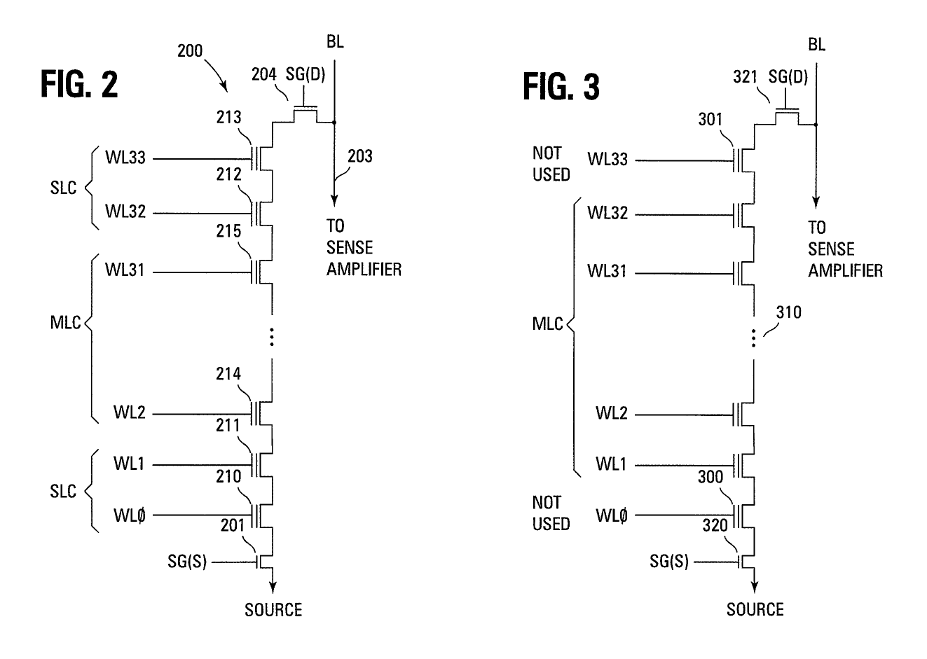

FIG. 2 illustrates a NAND series string 200 of memory cells that incorporates two additional memory cells. The series string 200 is coupled to a transfer line, such as the bit line 203, through a select gate drain transistor 204 and to the array source line through a select gate source transistor 201. Control of the select gate drain transistor 204 is through the SGD signal and control of the select gate source transistor 201 is through the SGS signal.

The series string 200 of FIG. 2 is comprised of 34 memory cells 210-215. The memory cells 210-215 of the string 200 are each coupled to a different select line, such as one of word lines WL0-WL33. The “lowest” memory cell 210 is coupled to word line WL0 at the bottom of the series string 200 and the “highest” memory cell 213 is coupled to word line WL33 at the top of the series string 200. The word line labels are for purposes of illustration only as the present embodiments are not limited to any one word line orientation.

The series string of memory cells 200 of FIG. 2 programs two memory cells 210, 211 and 212, 213 on each end of the string 200 as single level cell (SLC) memory cells. The remaining memory cells between these end memory cells 210-213 are programmed as multiple level cell (MLC) memory cells. Since, as discussed above, the end parts of the series string 200 are typically less reliable than the remainder of the string 200 due to GIDL, using more reliable SLC memory cells that require lower programming voltages at these ends can increase the reliability of the string 200.

As discussed previously, non-volatile memory cells, such as flash memory cells, can be programmed as SLC or MLC. Each cell's threshold voltage (Vₜ) determines the data that is stored in the cell. For example, in an SLC, a Vₜ of 0.5V might indicate a programmed cell (i.e., logical 0 state) while a Vₜ of −0.5V might indicate an erased cell (i.e., logical 1 state).

A multiple level cell has multiple V, ranges that each indicate a different state. Multiple level cells take advantage of the analog nature of a traditional flash cell by assigning a digital bit pattern to a specific voltage range stored on the cell. This technology permits the storage of two or more bits per cell, depending, for example, on the quantity of voltage ranges assigned to the cell.

For example, a cell may be assigned four different voltage ranges of 200 mV for each range. Typically, a dead space or margin of 0.2V to 0.4V is between each range. If the voltage stored on the cell is within the first range, the cell is storing a 11 and is considered erased. If the voltage is within the second range, the cell is storing a 01. This continues for as many ranges that are used for the cell. In one embodiment, 11 is the most negative threshold voltage range while 10 is the most positive threshold voltage range. Alternate embodiments assign the logical states to different threshold voltage ranges.

The embodiments of the present disclosure are not limited to two bits per cell. Some embodiments may be programmed to more than two bits per cell, depending, for example, on the quantity of different voltage ranges that can be differentiated on the cell.

During a typical prior art programming operation, the selected word line for the flash memory cell to be programmed is biased with a series of programming pulses that start at a voltage that, in one embodiment, is greater than 16V with each subsequent pulse voltage increasing incrementally until the cell is programmed or a maximum programming voltage is reached. Each programming pulse moves the cell Vₜ closer to its target voltage.

A verification operation with a word line voltage of approximately 0V is performed between each programming pulse to determine if the floating gate is at the target threshold voltage. The unselected word lines for the remaining cells are typically biased at approximately 10V during the program operation. In one embodiment, the unselected word line voltages can be any voltage equal to or greater than ground potential. Each of the memory cells is programmed in a substantially similar fashion.

In one embodiment, programming of the embodiment of FIG. 2 begins at the bottom-most memory cell 210. Such a programming operation programs the first two cells 210, 211 as SLC memory cells. The next thirty memory cells are programmed as MLC. Then the remaining two memory cells 212, 213 at the top of the series string are programmed as SLC cells.

Even though SLC's and MLC's are mixed in the embodiments of the present disclosure in order to improve reliability, a certain memory capacity should still be maintained. In one embodiment, this capacity is expressed as 2^{N} memory cells, where N is determined by memory device specification during design and manufacture of the integrated circuit. In one embodiment, N is 5. Also, M=N+1.

FIG. 3 illustrates an alternate embodiment of a NAND series string of memory cells that incorporates two additional memory cells. This embodiment uses two “dummy” cells 300, 301 on each end of the series string. The dummy cells 300, 301 are not used for programming.

In this embodiment, the cell 300 coupled to the WL0 word line and closest to the select gate source transistor 320 is not used. Similarly, the cell 301 coupled to the WL33 word line and closest to the select gate drain transistor 321 is also not used. The remaining memory cells 310 of the series string of memory cells are programmed as MLC cells.

Programming of the series string of memory cells in this embodiment skips the lowest memory cell 300. The next thirty-two memory cells 310 are programmed as MLC cells. Finally, the remaining memory cell 301 at the top of the series string is skipped during programming.

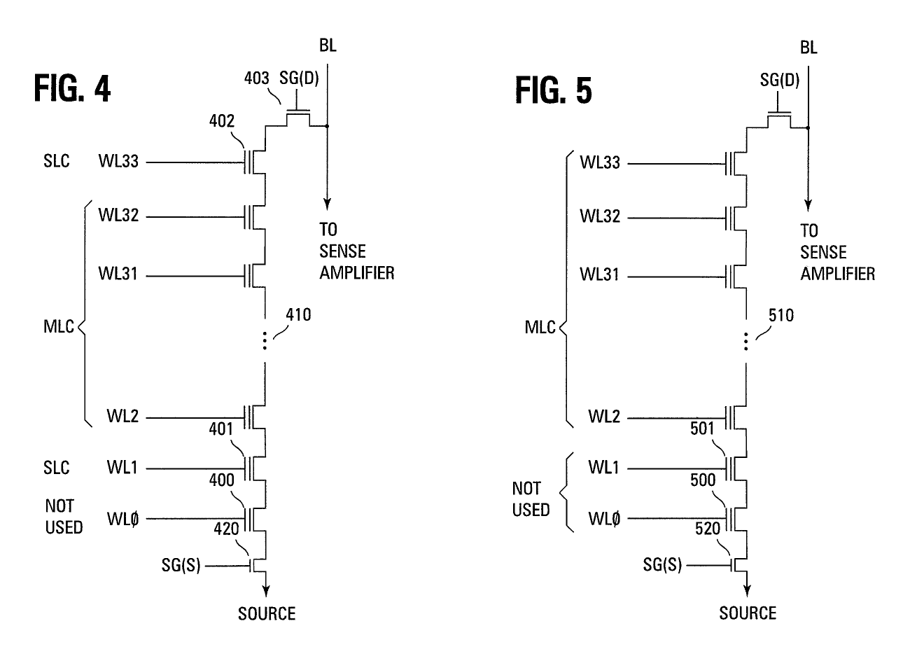

FIG. 4 illustrates another alternate embodiment of a NAND series string of memory cells that incorporate two additional memory cells. This embodiment uses one dummy cell 400 that is located at the bottom of the string closest to the select gate source transistor 420. The dummy cell 400 is not used for programming.

An additional cell 401 on word line WL1 is programmed/read as an SLC cell. Similarly, the top-most memory cell 402 of the series string of memory cells is programmed/read as an SLC cell. This cell is coupled to word line WL33 and is the memory cell closest to the select gate drain transistor 403.

Programming of the series string of memory cells in this embodiment skips the lowest memory cell 400 of the string. The next memory cell 401 is programmed as an SLC memory cell. The next thirty-one memory cells 410 are then be programmed as MLC cells. Finally, the remaining memory cell 402 at the top of the series string is programmed as an SLC cell.

FIG. 5 illustrates yet another embodiment of a NAND series string of memory cells that incorporate two additional memory cells. This embodiment uses two dummy memory cells 500, 501 that are both located at the bottom of the series string near the select gate source transistor 520. These memory cells 500, 501 are coupled to word lines WL0 and WL1, respectively, and are not programmed or read during normal operation of the series string. The remaining memory cells 510 of the series string, in this embodiment, are programmed/read as MLC memory cells.

Programming of the series string of memory cells in this embodiment skips the first two memory cells 500, 501. The remaining thirty-two memory cells 510 are then programmed as MLC memory cells.

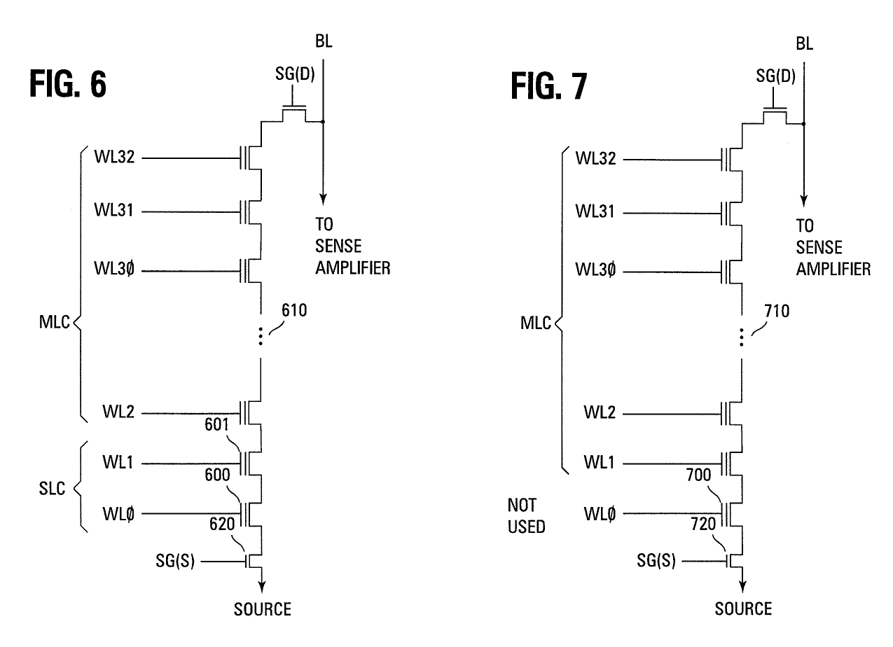

FIG. 6 illustrates an embodiment of a NAND series string of memory cells that incorporates one additional memory cell such that the series string is comprised of 33 memory cells. This embodiment programs/reads the lower two memory cells 600, 601 on word lines WL0 and WL1 as SLC memory cells. These memory cells 600, 601 are closest to the select gate source transistor 620. The remaining memory cells 610 of the series string of memory cells are programmed/read as MLC cells.

Programming of the series string of memory cells in this embodiment programs the first two memory cells 600, 601 as SLC memory cells. The remaining memory cells 610 of the series string are then programmed as MLC memory cells.

FIG. 7 illustrates another embodiment of a NAND series string of memory cells that incorporates one additional memory cell. In this embodiment, the lowest memory cell 700 on WL0 is a dummy memory cell that is not used in the same manner as the majority of the other memory cells (e.g.; it is neither programmed nor read during normal operation of the series string of memory cells). This memory cell 700 is the memory cell closest to the select gate source transistor 720. The remaining memory cells 710 of the series string are programmed/read as MLC memory cells.

Programming of the series string of memory cells in this embodiment skips programming of the bottom-most memory cell 700. The remaining memory cells 710 of the series string are then programmed as MLC memory cells.

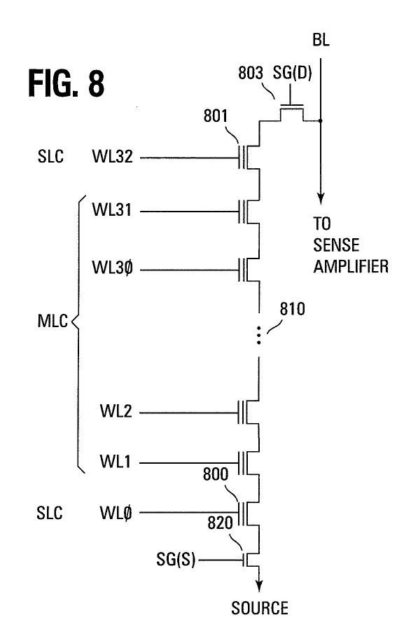

FIG. 8 illustrates still another embodiment of a NAND series string of memory cells that incorporates one additional memory cell. In this embodiment, the lowest memory cell 800 that is closest to the select gate source transistor 820 and coupled to word line WL0 is programmed/read as an SLC memory cell. Similarly, the top-most memory cell 801 of the series string that is closest to the select gate drain transistor 803 and coupled to word line WL32 is programmed/read as an SLC memory cell. The remaining memory cells 810 of the series string of memory cells are programmed/read as MLC memory cells.

Programming of the series string of memory cells in this embodiment programs the lowest memory cell 800 as an SLC cell. The next thirty-one memory cells 810 are programmed as MLC memory cells. The remaining memory cell 801 at the top of the series string is programmed as an SLC memory cell.

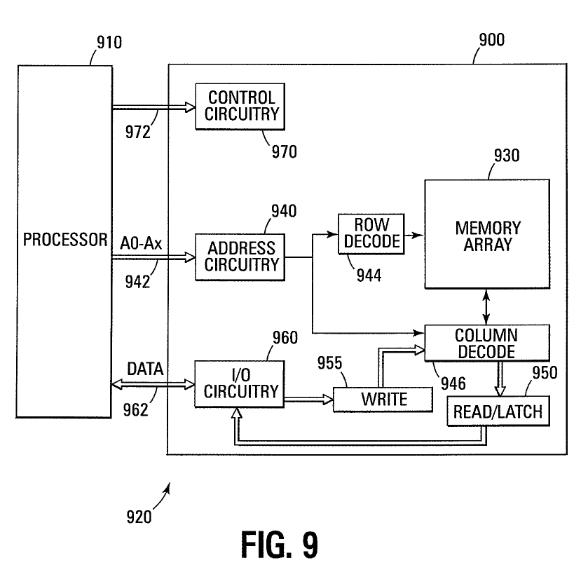

FIG. 9 illustrates a functional block diagram of a memory device 900 that can incorporate the non-volatile memory array 930 of the present embodiments. The processor 910 may be a microprocessor or some other type of controlling circuitry. The memory device 900 and the processor 910 form part of a memory system 920. The memory device 900 has been simplified to focus on features of the memory that are helpful in understanding the present invention.

The memory device 900 includes an array 930 of non-volatile memory cells as described above. The memory array 930 is arranged in banks of rows and columns. In one embodiment, the columns of the memory array 930 are comprised of the series strings of memory cells illustrated in the embodiments of FIGS. 2-8. As is well known in the art, the connections of the cells to the bitlines determines whether the array is a NAND architecture, an AND architecture, or a NOR architecture. While the above-described embodiments refer to NAND-type connections, the present embodiments are not limited to any one array architecture.

Address buffer circuitry 940 is provided to latch address signals provided on address input connections A0-Ax 942. Address signals are received and decoded by a row decoder 944 and a column decoder 946 to access the memory array 930. It will be appreciated by those skilled in the art, with the benefit of the present description, that the number of address input connections depends on the density and architecture of the memory array 930. That is, the number of addresses increases with both increased memory cell counts and increased bank and block counts.

The memory device 900 reads data in the memory array 930 by sensing voltage or current changes in the memory array columns using sense/buffer circuitry 950. The sense/buffer circuitry 950, in one embodiment, is coupled to read and latch a row of data from the memory array 930. Data input and output buffer circuitry 960 is included for bidirectional data communication over a plurality of data connections 962 with the controller 910. Write circuitry 955 is provided to write data to the memory array.

Control circuitry 970 decodes signals provided on control connections 972 from the processor 910. These signals are used to control the operations on the memory array 930, including data read, data write (program), and erase operations. The control circuitry 970 may be a state machine, a sequencer, or some other type of controller. The control circuitry 970, in one embodiment, can control the operations of the memory array on a cell-by-cell basis. For example, the memory cells of the NAND series string illustrated in FIG. 2 can be independently read and programmed. Additionally, the SLC and MLC can be decided based on an address of each memory cell.

The flash memory device illustrated in FIG. 9 has been simplified to facilitate a basic understanding of the features of the memory. A more detailed understanding of internal circuitry and functions of flash memories are known to those skilled in the art.

### Conclusion

In summary, the above-described embodiments share the common trait of including at least one extra memory cell in the series string of memory cells. The cell can be either at the top of the string nearest the select gate drain transistor, at the bottom of the string nearest the select gate source transistor, or at both the top and the bottom of the series string. The extra memory cell(s) can be, for example, either unused “dummy” cell or cells that are programmed to a different bit density (i.e., operated as SLC cells). These extra cells can reduce GIDL in the string by reducing the programming voltages required on either end of the string.

Although specific embodiments have been illustrated and described herein, it will be appreciated by those of ordinary skill in the art that any arrangement that is calculated to achieve the same purpose may be substituted for the specific embodiments shown. Many adaptations of the invention will be apparent to those of ordinary skill in the art. Accordingly, this application is intended to cover any adaptations or variations of the invention. It is manifestly intended that this invention be limited only by the following claims and equivalents thereof.

What is claimed is:

1. A series string of memory cells comprising:
a first end coupled to a transfer line;
a second end coupled to a source; and
a plurality of memory cells coupled between the first end and the second end wherein at least one memory cell closest to the second end is programmed to a different bit density than a majority of the plurality of memory cells.

2. The series string of memory cells of claim 1 wherein the at least one memory cell is programmed as a single level cell and the remainder of the plurality of memory cells are programmed as multiple level cells.

3. The series string of memory cells of claim 1 wherein a subset of the plurality of memory cells closest to the second end is programmed as single level cells and the remainder of the plurality of memory cells are programmed as multiple level cells.

4. The series string of memory cells of claim 1 wherein a first subset of the plurality of memory cells closest to the second end is programmed as single level cells, a second subset of the plurality of memory cells closest to the first end is programmed as single level cells, and the remainder of the plurality of memory cells are programmed as multiple level cells.

5. The series string of memory cells of claim 4 wherein the first and second subsets are each comprised of two memory cells.

6. The series string of memory cells of claim 4 wherein the first and second subsets are each comprised of one memory cell.

7. The series string of memory cells of claim 1 and further including:
a select gate drain transistor coupled between the first end and the bit line; and
a select gate source transistor coupled between the second end and the source line.

8. A series string of memory cells comprising:
a first end coupled through a select gate drain transistor to a bit line;
a second end coupled through a select gate source transistor to a source line; and
a plurality of memory cells coupled between the first end and the second end wherein a first memory cell closest to the select gate source transistor is not used and a remainder of the plurality of memory cells is programmed as multiple level cells.

9. The series string of memory cells of claim 8 wherein a second memory cell closest to the select gate drain transistor is not used.

10. The series string of memory cells of claim 8 wherein the at least one of the memory cells is programmed and/or read in accordance with a different number of potential states than the majority of the plurality of memory cells.

11. The series string of memory cells of claim 8 wherein a second memory cell, adjacent to the first memory cell is programmed at a lower bit density than the remainder of the plurality of memory cells and a third memory cell closest to the select gate drain transistor is programmed at the lower bit density.

12. The series string of memory cells of claim 11 wherein the lower bit density is single level cell.

13. A memory device comprising:
control circuitry for controlling operation of the memory device; and
a memory array, coupled to the control circuitry, comprising:
a plurality of series strings of memory cells, each series string comprising a first end and a second end and a plurality of memory cells between the first and second ends wherein a first subset of the plurality of memory cells is adjacent to the first end and a second subset of the plurality of memory cells is adjacent to the second end and a remaining quantity of memory cells between the first and second subsets are programmed to a higher bit density than the first and second subsets.

14. The memory device of claim 13 wherein the memory device is a NAND flash memory device.

15. The memory device of claim 13 wherein both the first and second subsets are each comprised of two memory cells and are programmed as single level cells and the remaining quantity of memory cells are programmed as multiple level cells.

16. The memory device of claim 13 and further including:
a select gate drain transistor coupling the first end to a bit line;
a select gate source transistor coupling the second end to a source line; and
a word line that couples rows of adjacent series strings of memory cells.

17. The memory device of claim 13 wherein the first and second subsets are each comprised of one memory cell and are not used.

18. The memory device of claim 13 wherein the first subset is comprised of one memory cell that is programmed as a single level cell and the second subset is comprised of two memory cells wherein a first cell that is adjacent to a select gate source transistor is not used, the second cell is programmed as a single level cell, and the remaining quantity of memory cells of the series string are programmed as multiple level cells.

19. A method for programming a memory device, the method comprising:
programming at a first bit density at least one memory cell, of a series string of memory cells, closest to a source line of the memory device; and
programming a remaining quantity of memory cells of the series string of memory cells at a second bit density that is higher than the first bit density.

20. The method of claim 19 wherein programming at the first bit density comprises:
programming, at the first bit density, two memory cells at a first end closest to the source line; and
programming, at the first bit density, two memory cells at a second end of the series string of memory cells that are closest to a bit line.

21. The method of claim 19 wherein programming at the first bit density comprises programming as a single level cell and programming at the second bit density comprises programming as a multiple level cell.

22. The method of claim 19 wherein programming at the first bit density comprises programming, at the first bit density, two memory cells at a first end closest to the source line.

23. The method of claim 19 wherein programming at the first bit density comprises:
programming, at the first bit density, one memory cell at a first end closest to the source line; and
programming, at the first bit density, one memory cell at a second end of the series string of memory cells closest to a bit line.

24. A memory device comprising;
control circuitry for controlling operation of the memory device; and
a memory array, coupled to the control circuitry, comprising:
a plurality of series strings of memory cells, each series string comprising a first end and a second end and a plurality of memory cells between the first and second ends wherein the number of the memory cells is more than 2^{N} and less than 2^{M} wherein (M=N+1), and the controller is configured to control the memory cells on a cell-by-cell basis.

25. The memory device of claim 24 wherein N is device specific, is determined at manufacture of the device and wherein N=5.
